(19) United States
(12) Patent Application Publication
(10) Pub. No.: US 2006/0273452 A1
(43) Pub. Date: Dec. 7, 2006

(54) Semiconductor package and fabrication method thereof

(75) Inventors: Ho-Yi Tsai, Taichung Hsien (TW); Chien-Ping Huang, Hsinchu Hsein (TW); Hung-Min Shun, Taichung (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/445,540

(22) Filed: Jun. 2, 2006

(30) Foreign Application Priority Data
Jun. 2, 2005 (TW) 094118113

(51) Int. Cl. H01L 23/34

(52) U.S. Cl. 257/706

(57) ABSTRACT

A semiconductor package and a fabrication method thereof are provided. During a molding process, a substrate mounted with a chip is placed in a mold having a molding cavity, wherein the molding cavity is sized larger than the predetermined size of the semiconductor package, and a portion of the mold for clamping the substrate is located outside a circuit layout area of the substrate. Thereby, an encapsulant subsequently formed for encapsulating the chip is sized larger than the predetermined size of the semiconductor package. Then, a singulation process is performed to remove portions of the encapsulant and portions of the substrate unit larger in size than the predetermined size of the semiconductor package, such that damage to circuits of the substrate can be prevented. Further, during the fabrication processes, a heat sink may be mounted on the chip to form a thermally enhanced semiconductor package.

### FIELD OF THE INVENTION

The present invention relates to semiconductor packages and fabrication methods thereof, and more particularly, to a semiconductor package and a fabrication method thereof, which can be integrated with a heat sink and prevent damage to circuits of a substrate during molding process.

### BACKGROUND OF THE INVENTION

Along with the great progress in portable communications products, networking, and computers, the BGA (Ball Grid Array) package with high density and multi-pins for minimizing integrated circuit (IC) area is becoming mainstream, and such packages are suitable for high-performance chips such as micro processors, chipsets and graphic chips, which process calculations with high speed. The BGA package is an advanced semiconductor packaging technology which is characterized by mounting a semiconductor chip on a substrate and implanting a plurality of solder balls arranged in a grid array on the back side of the substrate in order to facilitate more input/output (I/O) connections on the semiconductor chip carrier in the same area than prior technologies—an important characteristic required by semiconductor chips exhibiting high integration—such that the entire package can be bonded and electrically connected to external devices by the solder balls.

Referring to FIGS. 1A to 1C, a conventional semiconductor package (for example, a BGA package) using a substrate as a chip carrier is disclosed in U.S. Pat. Nos. 5,652,185 and 6,552,428. During a molding process, a chip is encapsulated by an encapsulant on a surface of the substrate. As shown in the drawings, during the molding process, a substrate 11 adhered with a chip 10 is clamped in a mold having an upper mold 12 and a lower mold 13, such that a clamping area of the upper mold 12 is corresponded to a predetermined mold clamp line (MCL) on the substrate 11. The upper mold 12 has a molding cavity 120 for injecting resin therein from a molding gate 110. Thereby an encapsulating material is injected for encapsulating the semiconductor chip 10 until the molding cavity 120 is fully filled, so as to form an encapsulant 14 such that damage to the semiconductor chip 10 from moisture or contamination of external environment can be prevented. During a subsequent singulation process, the substrate 11 is punched along predetermined punch lines (so-called PKG lines) at locations P of the package. In other words, the substrate 11 is punched along the punching line of the substrate 11 to form the required semiconductor package, wherein the encapsulant 14 is sized smaller than the substrate 11 of the semiconductor package.

During the molding process, the substrate adhered with a chip is clamped between the upper mold and the lower mold for injecting the resin subsequently, however, if the clamping pressure is too large, micro-cracking may occur on the solder mask coated on the surface of the substrate due to the improper force exerted thereon, and more seriously, circuits of the substrate may crack, adversely affecting electrical performance and reliability of the finished package. Furthermore, if the clamping pressure is decreased to avoid the above-mentioned problems, space may appear between the upper surface of the substrate and the lower surfaces of the molds such that resin may leak into the space to cause mold flash of the substrate surface where it should not be covered by the encapsulant. Although the mold flash can be removed after the molding process, but such removal process increases the cost of production and causes an extra fabricating process, and the removal process may damage the substrate or the encapsulant, thereby decreasing the yield of products.

Referring to FIG. 2, a dam-shaped structure 25 mounted on the surface of the substrate 21 is disclosed in U.S. Pat. No. 5,744,084. The dam-shaped structure 25 is employed for receiving the clamp area of the upper mold 22, so as to prevent mold flash from occurring. However, such dam-shaped structure 25 has to be produced by a separate process after the circuit layout of the substrate and the process is complicated, so it is not a practical and cost-efficient way for package fabrication; moreover the dam-shaped structure still cannot avoid damage to the substrate mentioned above.

Further referring to FIG. 3A and FIG. 3B, another fabrication method for a conventional semiconductor package is illustrated as disclosed in U.S. Pat. No. 6,452,268. An upper mold 32 of a mold is formed with a recess 321 extending outward, such that the resin can be flowed into a molding cavity 320 of the upper mold 32 by molding injection after the upper mold 32 is fit to the lower mold 33 to clamp the substrate 31. Then, the melted resin flowing in the recess 321 of the upper mold accelerates heat absorption of the mold because of the narrowing flow channel. Accordingly, the adhesion of mold flow is increased and the flowing speed thereof is decreased so as to avoid resin flow from flashing over the joints between the substrate 31 and the upper mold 32. Therefore, after the molding process is completed, the encapsulant 34 for encapsulating the semiconductor chip 30 has formed and the resin flowed into the recess 321 has solidified to form a shoulder 341 extending from the bottom of the encapsulant 34.

Although, the force in clamping the mold may be decreased by the formation of the recess of the upper mold via the foregoing fabrication process, the process is still limited in effectively preventing damage to the circuits of the substrate. For example, when the process is used in a build-up substrate of an advanced chip package, the degree of sensitivity in clamping the mold is higher as the width of substrate's circuits may be minimized to about 20 μm, so problems relating to damage to the substrate's circuits caused by improper clamping force exerted on the substrate during molding still cannot be overcome by the foregoing fabrication method. Moreover, as the aforementioned fabrication method needs to change the design of the mold, an extra process is required, so as to form a recess in the upper mold, thereby increasing the costs of production.

Furthermore, as a huge amount of heat is generated during the operation of semiconductor chip with high integration, the performance and the usage life of the semiconductor is likely to be adversely affected if there is no effective way to dissipate heat for the semiconductor chip.

Accordingly, a need still remains for providing a semiconductor package and a fabrication method thereof, which can effectively prevent damage to circuits caused by molding pressure during molding and enhance heat dissipation efficiency of the BGA semiconductor package without increasing processing the costs of production.

Solutions to these problems have been long sought but prior developments have not taught or suggested any solutions and, thus, solutions to these problems have long eluded those skilled in the art.

### SUMMARY OF THE INVENTION

In light of the drawbacks of the above prior arts, it is a primary objective of the present invention to provide a semiconductor package and a fabrication method thereof, which can avoid damage to substrate circuitry during molding.

It is another objective of the present invention to provide a semiconductor package and a fabrication method thereof, which can avoid damage to substrate circuitry during molding without using a mold requiring an extra process for forming into a particular shape.

It is a further objective of the present invention to provide a semiconductor package and a fabrication method thereof, which can allow a heat sink to be mounted on a chip to form a thermally enhanced semiconductor package.

To achieve the above-mentioned and other objectives, the present invention proposes a semiconductor fabrication method comprising the steps of: providing a substrate module having a plurality of substrate units, wherein to at least a semiconductor chip is mounted on and electrically connected to each of the substrate units; placing each of the substrate units mounted with the semiconductor chips in a mold having a molding cavity for filling resin therein, such that a plurality of independent encapsulants for encapsulating the semiconductor chips are formed on the substrate module and corresponded to each substrate unit, wherein each encapsulant may be sized larger than a predetermined size of the semiconductor package; and performing a singulation process along the predetermined outlines of the semiconductor package to remove portions of the encapsulant and portions of the substrate unit that are larger in size than the predetermined size of the semiconductor package. Moreover, a plurality of solder balls may be implanted on a back surface of the substrate unit.

Furthermore, another embodiment for a semiconductor package and a fabrication method thereof of the present invention is configured to have a heat sink being mounted on the chip to enhance the heat dissipation efficiency of the semiconductor chip. The fabrication method comprises steps of: providing a substrate module having a plurality of substrate units, wherein to at least a semiconductor chip is mounted on and electrically connected to each of the substrate units; mounting a heat sink on the chip of each substrate unit; placing each of the substrate units mounted with the semiconductor chip and the heat sink in a mold having a molding cavity for filling resin therein, such that a plurality of independent encapsulants for encapsulating the semiconductor chips and the heat sinks are formed on the substrate module and corresponded to each substrate unit, wherein each encapsulant is sized larger than a predetermined size of the semiconductor package; and performing a singulation process along the predetermined outlines of the semiconductor package to remove portions of the encapsulant and portions of the substrate unit that are larger in size than the predetermined size of the semiconductor package. Moreover, a plurality of solder balls may be implanted on a back surface of the substrate unit. Furthermore, the heat sink may be sized larger or smaller than the predetermined size of the semiconductor package.

A semiconductor package is further disclosed in the present invention, comprising: a substrate unit having a first surface and a second surface opposed to the first surface; at least a semiconductor chip mounted and electrically connected to the first surface of the substrate unit; a heat sink mounted on the semiconductor chip; and an encapsulant formed on the first surface of the substrate unit for encapsulating the heat sink and the semiconductor chip, wherein the sides of the encapsulant and the edges of the substrate unit are parallel to each other. The semiconductor package may further comprise a plurality of solder balls implanted on the second surface of the substrate unit. Furthermore, the heat sink may be sized larger than the predetermined size of the semiconductor package to allow the edges of the heat sink to be flush with the sides of the encapsulant and the substrate unit by cutting the heat sink and the encapsulant into equally sized pieces, or alternatively, the heat sink may be sized smaller than the predetermined size of the semiconductor package so that the heat sink may be embedded in the encapsulant entirely.

Accordingly, the semiconductor package and the fabrication method thereof of the present invention involves placing the substrate unit mounted with the chip in the mold having the molding cavity during the molding process, wherein the molding cavity is sized larger than the predetermined size of the semiconductor package, such that a portion of the mold for clamping the substrate unit is located outside a circuit forming area of the substrate to prevent damage to the circuits of the substrate unit; subsequently forming an encapsulant for encapsulating the chip by filling resin into the molding cavity, wherein the encapsulant may be sized larger than the predetermined size of the semiconductor package; and then performing the singulation process to remove portions of the encapsulant and portions of substrate unit larger in size than the predetermined size of the semiconductor package, such that damage to circuits of the substrate caused by the clamp area of the mold can be prevented.

Furthermore, in the present invention, a heat sink may be mounted on the chip during packaging processes to dissipate heat generated during chip operation, so as to form a semiconductor package that can improve efficiency of heat dissipation for a chip.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF DRAWINGS

FIGS. 1A to 1C (PRIOR ART) are schematic cross-sectional views showing the procedural steps of a conventional method for fabricating a semiconductor package;

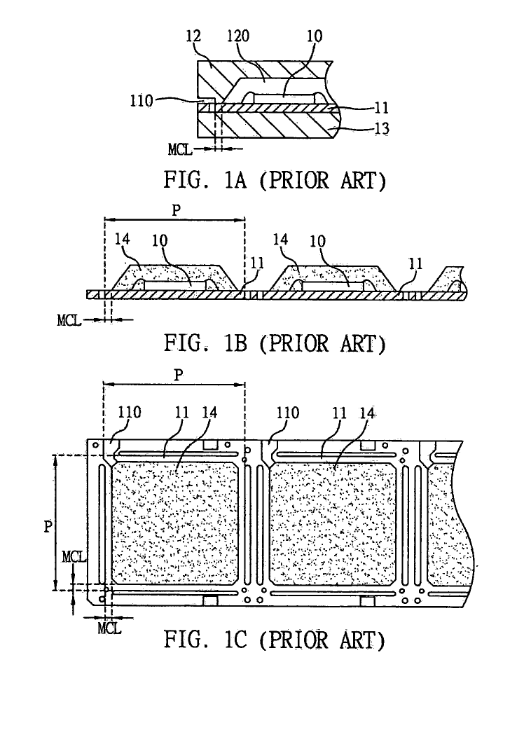

FIG. 2 (PRIOR ART) is a schematic cross-sectional view showing a dam-shaped structure mounted on a surface of a substrate as disclosed in U.S. Pat. No. 5,744,084;

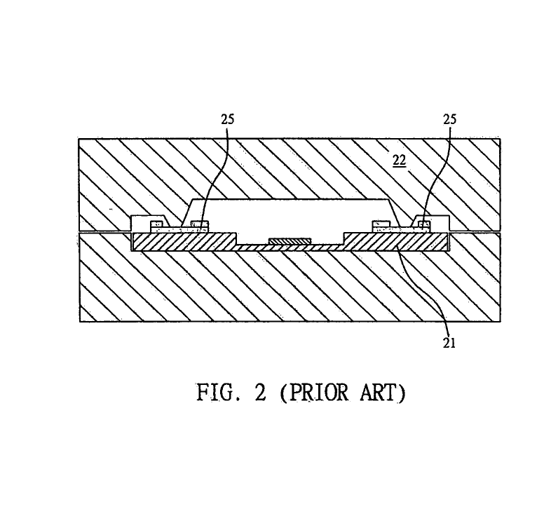

FIGS. 3A to 3B (PRIOR ART) are schematic cross-sectional views showing a fabrication method of a semiconductor package disclosed in U.S. Pat. No. 6,452,268;

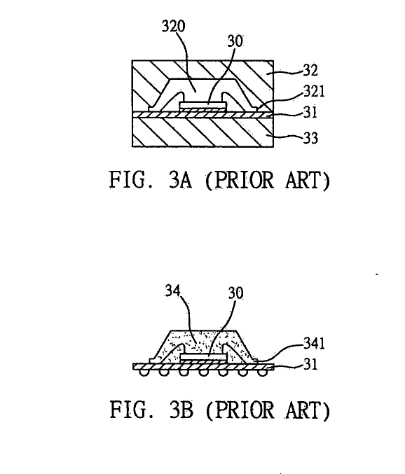

FIGS. 4A to 4E are schematic cross-sectional views showing a fabrication method of a semiconductor package according to a first embodiment of the present invention;

FIGS. 5A to 5D are schematic cross-sectional views showing a fabrication method of a semiconductor package according to a second embodiment of the present invention;

FIG. 6 is a schematic cross-sectional view showing a semiconductor package according to a third embodiment of the present invention; and

FIG. 7 is a schematic cross-sectional view showing a semiconductor package according to a fourth embodiment of the present invention.

### DETAILED DESCRIPTION OF THE INVENTION

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

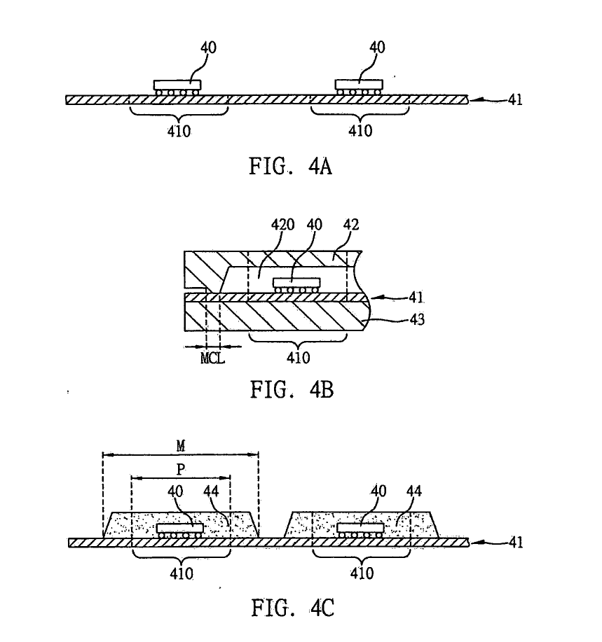

FIG. 4A to FIG. 4E shows a fabrication method of a semiconductor package according to a first embodiment of the present invention. It should be noted the drawings are simplified cross-sectional views illustrating only the basic structure of the present invention.

As shown in FIG. 4A, a substrate module 41 comprising a plurality of substrate units 410 is provided, wherein the substrate units 410 may be arranged in an array or in a line. Then, at least a semiconductor chip 40 is mounted and electrically connected to each substrate unit 410. The semiconductor chip 40 may be electrical connected to the substrate unit via the use of bonding wires, as well as the flip-chip method shown in the drawings. In one embodiment, the substrate unit may be a build-up substrate.

As shown in FIG. 4B and FIG. 4C, the substrate module 41 mounted with the semiconductor chip 40 is placed in a mold having an upper mold 42 and a lower mold 43. The upper mold 42 has a molding cavity 420 for filling resin therein via an feed opening provided in injection molding, so as to form an encapsulant 44 for encapsulating the semiconductor chip 40, such that damage to the semiconductor chip 40 caused by moisture, pollution or contamination from the external environment can be prevented. The planar size M of the mold cavity 420 is larger than the predetermined planar size P (as shown by the dashed lines in the drawings) of the semiconductor package. In other words, the mold clamp line (MCL) for clamping the clamping area of the substrate module 41 is located outside a circuit layout area of the substrate unit 410, so as to avoid damage to circuits of the substrate unit 410 caused by the mold, thereby allowing a semiconductor package with good electrical performance to be formed by injecting resin in the molding cavity 420 of the mold to form the encapsulant 44 subsequently for encapsulating the semiconductor chip 40.

Furthermore, referring to FIG. 4D, a plane view is illustrated showing the formation of the encapsulant for encapsulating a semiconductor chip corresponding to each substrate unit 410 on the substrate module 41, wherein the planar size M of the encapsulant is larger than the predetermined planar size P of the semiconductor package.

As shown in FIG. 4E, a singulation process using cutting tools such as a singulation saw is performed to cut along the lines of the predetermined area P (shown by the dashed lines in FIG. 4D), such that portions of the encapsulant 44 and the substrate units 410 larger in size than the predetermined size of the package are removed and the substrate units 410 are separated without concern of damage to the circuits of the substrate caused by the clamping area of the mold. Moreover, a plurality of solder balls (not shown in the drawing) can be implanted on the back surface of each substrate unit to electrically connect the semiconductor package to external devices.

### Second Embodiment

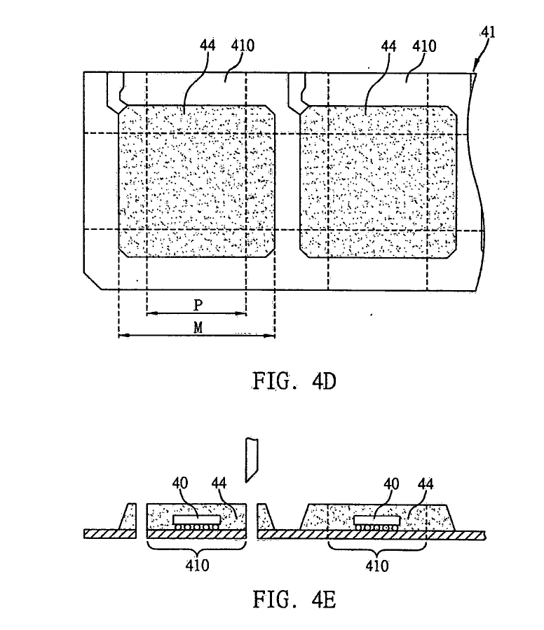

FIG. 5A to FIG. 5D are schematic cross-sectional views showing a fabrication method of a semiconductor package according to a second embodiment of the present invention. The fabrication method of the second embodiment is similar to that of the first embodiment, the main difference in the second embodiment being that before package molding and singulation are performed, the mounting of a heat sink is performed directly on the semiconductor chips of each substrate unit once at least a semiconductor chip is mounted and electrically connected on the substrate unit. By the use of a heat sink in this configuration, the heat dissipation efficiency of the semiconductor package can be enhanced.

As shown in FIG. 5A, a substrate module 51 having a plurality of substrate units 510 is provided, allowing at least a semiconductor chip to be mounted and electrically connected to each substrate unit 510. It should be noted that although flip-chip attachment is depicted in the drawings, the method of electrically connecting the semiconductor chip to each substrate unit is not limited to flip-chip attachment.

As shown in FIG. 5B, a heat sink 55 is mounted on the semiconductor chips 50 corresponding to each substrate unit 510.

As shown in FIG. 5C, each substrate unit 510 mounted with a semiconductor chip 50 and a heat sink 55 is placed in a mold having a molding cavity for injecting resin in the mold, such that a plurality of encapsulants 54 are formed for encapsulating each combination of a semiconductor chip 50 and a heat sink 55, wherein the size M of the encapsulant 54 is larger than the predetermined size P of the semiconductor package, and the heat sink is sized larger than the predetermined size of the package.

As shown in FIG. 5D, a singulation process is performed to cut along the lines for the area of predetermined size P of the semiconductor package, thereby removing portions of the encapsulant 54, portions of the substrate unit 510, and portions of the heat sink 55 larger in size than the predetermined size of the package. Moreover, a plurality of solder balls (not shown in the drawings) may be implanted on the back surface of each substrate unit.

A semiconductor package is also disclosed in the present invention, comprising: a substrate unit 510 having a first surface and a second surface opposed to the first surface; at least a semiconductor chip 50 mounted and electrically connected to the first surface of the substrate unit 510; a heat sink 55 mounted on the semiconductor chip 50; and an encapsulant 54 formed on the first surface of the substrate unit 510 for encapsulating the heat sink 55 and the semiconductor chip 50, wherein the sides of the encapsulant 54 and the edges of the substrate unit 510 are flush with each other. The semiconductor package may further comprise a plurality of solder balls implanted on the second surface of the substrate. Furthermore, the heat sink is sized larger than the predetermined size of the semiconductor package in order to evenly cut each edge of the heat sink with the sides of the encapsulant and the edges of substrate such that they are flush with one another, such that the edges of the heat sink are exposed in the process. Therefore, heat produced during chip operation is dissipated by the heat sink to enhance usage life and efficiency of the semiconductor package.

### Third Embodiment

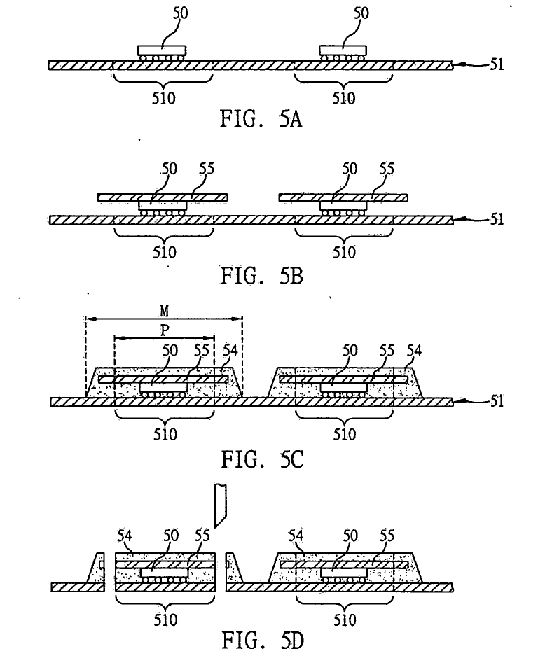

FIG. 6 shows a semiconductor package according to a third embodiment of the present invention. The semiconductor package of the third embodiment is similar to that of the second embodiment, the main difference in the third embodiment being that the semiconductor 60 is electrically connected to the substrate unit 610 via a plurality of bonding wires 66, such that the semiconductor chip 60 can be electrically connected to external devices by solder balls 67 implanted on the back surface of the substrate unit 610.

Furthermore, the bottom of the heat sink may be formed with a thermally-conductive protrusion 650 or separated by a pad so as to prevent the heat sink 65 of the semiconductor chip 60 from contacting the bonding wires 66, thereby preventing short circuits that could be formed by the heat sink 65 touching the bonding wires 66.

### Fourth Embodiment

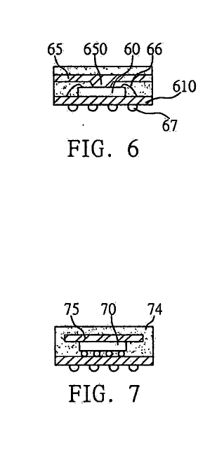

FIG. 7 shows a semiconductor package according to a fourth embodiment of the present invention. The semiconductor package of the fourth embodiment is similar to that of the second embodiment, the main difference in the fourth embodiment being that the heat sink 75 mounted on the semiconductor chip 70 is sized smaller than the predetermined size of the package, such that the heat sink 75 is entirely encapsulated in the encapsulant 74 in the subsequent molding and singulation process.

To form such a package, during molding, a substrate mounted with a chip is placed in a mold having a molding cavity, wherein the molding cavity is sized larger than the predetermined size of the semiconductor package, and a portion of the mold for clamping the substrate is located outside a circuit layout area of the substrate, so as to prevent damage to the circuits of the substrate. Due to the foregoing design and arrangement, an encapsulant subsequently formed for encapsulating the chip by injecting resin into the molding cavity is sized larger than the predetermined size of the semiconductor package. Then, a singulation process is performed to remove portions of the encapsulant and portions of substrate larger in size than the predetermined size of the semiconductor package, such that damage to the circuits of the substrate near the clamp area of the mold can be avoided.

Furthermore, during the fabrication processes, a heat sink may be mounted on the chip for dissipating heat generated during chip operation, such that a thermally enhanced semiconductor package is formed.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A fabrication method of a semiconductor package, comprising the steps of:
providing a substrate module having a plurality of substrate units mounted and electrically connected with at least a semiconductor chip on each of the substrate units;
placing each substrate unit mounted with at least a semiconductor chip in a mold having a molding cavity for filling resin therein, such that a plurality of independent encapsulants for encapsulating the semiconductor are formed on the substrate module at locations corresponding to each substrate unit, wherein the encapsulant is sized larger than a predetermined size of the semiconductor package; and
performing a singulation process along outlines corresponding to the predetermined size of the semiconductor package to remove portions of the encapsulant and portions of the substrate unit larger in size than the predetermined size of the semiconductor package.

2. The fabrication method of claim 1, wherein the substrate module is arranged in an array or in a line.

3. The fabrication method of claim 1, wherein the substrate unit is a build-up substrate.

4. The fabrication method of claim 1, wherein the semiconductor chips are electrically connected to the substrate units by flip-chip attachment or bonding wires.

5. The fabrication method of claim 1, wherein the molding cavity of the mold is sized larger than a predetermined size of the semiconductor package.

6. The fabrication method of claim 1, wherein a portion of the mold for clamping the substrate unit is located outside a circuit layout area of the substrate unit.

7. The fabrication method of claim 1, wherein, after mounting and electrically connecting at least a semiconductor chip on the substrate unit, the method further comprises:
mounting a heat sink on the chip of each substrate unit;
placing each substrate unit mounted with the semiconductor chip and the heat sink in a mold having a molding cavity for filling resin in the mold, such that a plurality of independent encapsulants for encapsulating the semiconductor chip and the heat sink are formed on the substrate module corresponding to each substrate unit, wherein the encapsulant is sized larger than a predetermined size of the semiconductor package; and
performing a singulation process along outlines corresponding to the predetermined size of the semiconductor package to remove portions of the encapsulant and portions of substrate unit larger in size than the predetermined size of the semiconductor package.

8. The fabrication method of claim 7, wherein the heat sink is initially sized larger than the predetermined size of the semiconductor package and then the heat sink is subsequently cut, such that one or more edges of the heat sink are flush with the corresponding sides of the encapsulant and the edges of the substrate unit.

9. The fabrication method of claim 7, wherein the heat sink is sized smaller than the predetermined size of the semiconductor package, such that the entire heat sink is embedded in the encapsulant.

10. The fabrication method of claim 7, wherein the heat sink is formed with a thermally-conductive protrusion facing toward the chip.

11. A semiconductor package, comprising:
a substrate unit having a first surface and a second surface opposed to the first surface;
at least a semiconductor chip mounted and electrically connected to the first surface of the substrate;
a heat sink mounted on the semiconductor chip; and
an encapsulant formed on the first surface of the substrate for encapsulating the heat sink and the semiconductor chip, wherein the sides of the encapsulant and the edges of the substrate unit are flush with each other.

12. The semiconductor package of claim 11, wherein the heat sink is initially sized larger than the predetermined size of the semiconductor package and then the heat sink is subsequently cut, such that one or more edges of the heat sink are flush with the corresponding sides of the encapsulant and the edges of the substrate.

13. The semiconductor package of claim 11, wherein the heat sink is sized smaller than the predetermined size of the semiconductor package, such that the entire heat sink is embedded in the encapsulant.

14. The semiconductor package of claim 11, further comprising a plurality of solder balls implanted on the second surface of the substrate.

15. The semiconductor package of claim 11, wherein the semiconductor chip is electrically connected to the substrate unit by flip-chip attachment or by bonding wires.

16. The semiconductor package of claim 11, wherein the heat sink is formed with a thermally-conductive protrusion facing toward the chip.
